(19) United States
(12) Patent Application Publication
(10) Pub. No.: US 2018/0059290 A1
(43) Pub. Date: Mar. 1, 2018

(54) ALUMINUM NITRIDE PROTECTION OF SILVER APPARATUS, SYSTEM AND METHOD

(71) Applicant: Freescale Semiconductor, Inc., Austin, TX (US)

(72) Inventors: Jeffrey Lynn WEIBRECHT, Gilbert, AZ (US); Colby Greg RAMPLEY, Phoenix, AZ (US); Minh-Phuong Thanh LE, Maricopa, AZ (US)

(21) Appl. No.: 15/244,922

(22) Filed: Aug. 23, 2016

(51) Int. Cl. G02B 1/14; G02B 5/08; C23C 14/22

(52) U.S. Cl. CPC G02B 1/14; C23C 14/22; G02B 5/0808

(57) ABSTRACT

A semiconductor apparatus including a wafer base with a top side and a bottom side, a silver base with a top side and a bottom side, wherein the bottom side of the silver base is attached to the top side of the wafer base and wherein the silver base provides a reflective surface, and an aluminum nitride protective layer attached to the top side of the silver base, wherein the aluminum nitride protective layer shields the silver base from the environment.

### FIELD OF THE INVENTION

The invention relates to the protection of a layer of silver, and more particularly, to utilizing aluminum nitride as a protective layer for silver.

### BACKGROUND

Silver has the highest reflectivity of any metal in the visible spectrum and is the preferred material of choice when creating mirrors. While silver is the preferred choice in optimum conditions, the use of silver has several critical limitations. On limitation is that silver readily oxidizes and loses its luster in a short period of time. The reflective properties of silver are degraded when silver is exposed to the environment. To overcome this limitation, protective layers have been placed upon the silver. Many of these protective layers, however, degrade the reflective properties of the silver and diminish the value of using silver as a reflective element. Additionally, many processes that apply a protective layer do not provide a uniform, thin protection layer during the application process. Subsequent processing of the silver may be negatively impacted without a uniform, thin protection layer.

One prior art method of providing a protective layer for silver is U.S. Pat. No. 5,076,663, entitled “Corrosion Protection for Silver Reflectors” which issued on Dec. 31, 1991. This prior art patent describes a method of protecting silver reflectors from damage caused by contact with gaseous substances which are often present in the atmosphere. The prior art patent describes a method that at least partially coats a reflector with a metal oxide such as aluminum oxide to a thickness of 15 .ANG. or less. The prior art, including U.S. Pat. No. 5,076,663, describe the use of metal oxides as protection layers for silver. The prior art requires the use of metal oxides, including RF plasma PVD sputtering of an Aluminum oxide target or other oxide materials.

Prior art methods of integration for mirror protection of silver include the use of Physical Vapor Deposition (“PVD”) to apply a thin aluminum oxide (AlOx) final layer. PVD, also known as Sputtering, is the process of creating a gas plasma typically of Argon and then accelerating the ions of the plasma at a target in order to deposit the material on to a substrate. This layer must be created without O2 plasma due to the readily oxidized exposed silver layer. To accomplish this, AlOx is deposited using PVD with RF plasma. One limitation of this process is that it has stability issues in maintaining a consistent and uniform film. Also, the applied layer requires non-standard RF sputtering due to the non-conducting nature of the ceramic (AlOx) target. This prior art method requires specific, expensive equipment and chambers. Another limitation is that the deposition rate of PVD of an aluminum oxide is time consuming.

Therefore, an improved method and system for providing a protection layer to silver without degrading the reflective properties of the silver throughout the visible spectrum is desired.

### BRIEF DESCRIPTION OF THE DRAWINGS

A more complete appreciation of the invention is provided by reference to the following detailed description of the appended drawings and figures. The following descriptions, in conjunction with the appended figures, enable a person having skill in the art to recognize the numerous advantages and features of the invention by understanding the various embodiments. These drawings are provided to facilitate the reader's understanding of the invention and shall not be considered limiting of the breadth, scope, or applicability of the invention. It should be noted that for clarity and ease of illustration these drawings are not necessarily made to scale. The following figures are utilized to best illustrate these features.

Some of the figures included herein illustrate various embodiments of the invention from different viewing angles. Although the accompanying descriptive text may refer to such views as “top,” “bottom” or “side” views, such references are merely descriptive and do not imply or require that the invention be implemented or used in a particular spatial orientation unless explicitly stated otherwise.

FIG. 1 is a diagram of a silver mirror with a protective layer according to one embodiment of the invention.

FIG. 2 is a diagram of a silver mirror with a protective layer on a wafer according to one embodiment of the invention.

FIG. 3 is a diagram of a PVD system with a wafer with a silver base according to one embodiment of the invention.

FIG. 4 is a flow diagram of the deposition of the aluminum nitride layer on the silver base according to one embodiment of the invention.

The figures are not intended to be exhaustive or to limit the invention to the precise form disclosed. It should be understood that the invention can be practiced with modification and alteration, and that the invention be limited only by the claims and the equivalents thereof.

### DETAILED DESCRIPTION OF THE INVENTION

A system and method for the application of an aluminum nitride protective layer on silver is disclosed. A substrate or wafer includes a silver, reflective layer. A protective layer of aluminum nitride is applied to the silver layer of the substrate or wafer. The aluminum nitride protective layer has minimal to no effect upon the reflectivity of the silver layer. The aluminum nitride protective layer is deposited on the silver layer through the use of Sputtering or PVD.

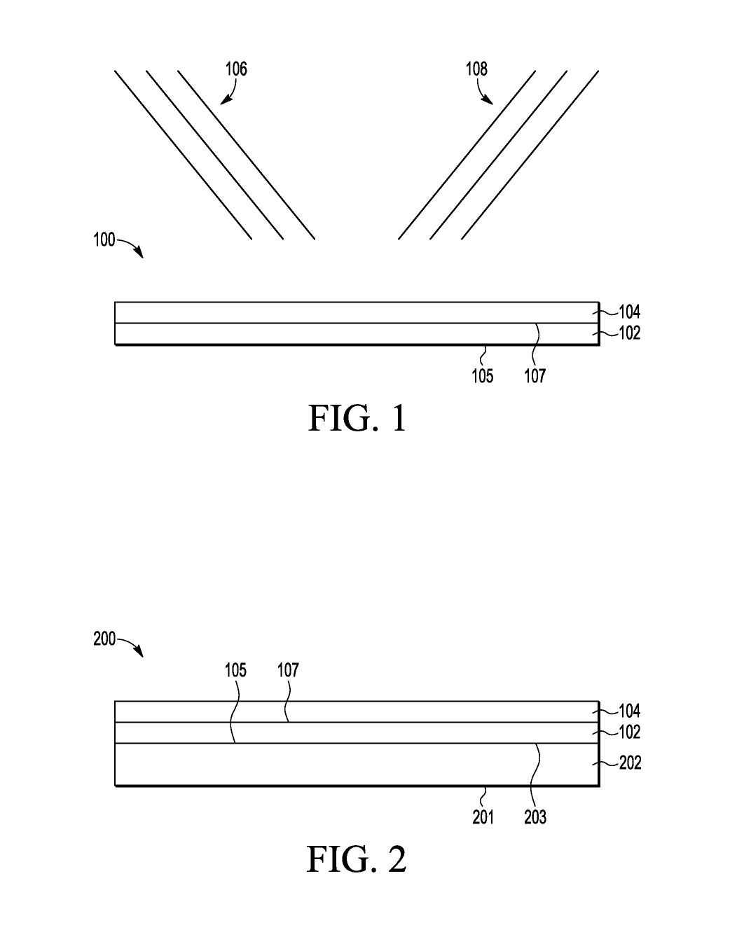

Referring now to FIG. 1, a diagram of a silver mirror with a protective layer according to an embodiment of the invention is disclosed. A silver mirror 100 is shown. The silver mirror 100 includes a silver base 102 and a protective layer 104. The silver base 102 includes a bottom side 105 and a top side 107. In one embodiment, the protective layer 104 is formed from aluminum nitride. The protective layer 104 is deposited on the silver base 102 through the use of PVD. The visible spectrum of light 106 strikes the silver mirror 100 and the silver mirror 100 reflects the reflective light 108. The aluminum nitride protective order 104 does not degrade the reflective properties of the silver base 102 which is reflecting the visible spectrum of light 106. The reflective properties of the silver mirror 100 with an aluminum nitride protective layer 104, according to one embodiment of the invention, are identical or nearly identical to the reflective properties of a bare silver base 102.

In one embodiment, the silver base 102 has a reflectance property of approximately 0.95 to 0.98 (or reflects approximately 95% to 98%) for light in the visible spectrum 106, or light having a wavelength within approximately 400 nm to 700 nm. It is noted that the reflectance property of the silver base 102 is different from the inherent material reflectivity of silver, where the reflectance property is largely determined by the thickness of the silver base. In one embodiment, the silver base 102 is thick enough to achieve approximately 0.95 to 0.98 reflectance for the visible spectrum of light 106. The thickness to achieve this reflectivity is approximately 2000 angstroms. However, a wide variety of thicknesses may be implemented without detracting from the spirit of the invention, including thicknesses that may be less than 2000 angstroms or more than 2000 angstroms. The addition of the protective layer 104 of aluminum nitride may reduce the reflectance property of the silver base, depending on the thinness of the aluminum nitride. In one embodiment, the protective layer 104 is thin enough to minimize any loss of reflectance. The thickness to achieve this result is a protective layer 104 of approximately 200 angstroms or less. This protective layer 104 thickness achieves substantially zero loss of reflectance (e.g., the resulting reflectance of the silver base with the protective layer is substantially unchanged from the reflectance of the silver base without the protective layer). In another embodiment, the protective layer 104 is thick enough to achieve a reflectance of 0.90 or greater, such as 0.92, or in a range of 0.92 to 0.98. In this embodiment, the protective layer 104 is thick enough to protect the silver base from the ambient environment (e.g., the silver base 102 minimizes any oxidation) while being thin enough to maintain reflectance at 0.90 or greater. However, a wide variety of protective layer 104 thicknesses may be implemented without detracting from the spirit of the invention.

Referring now to FIG. 2, a diagram of a silver mirror with a protective layer on a wafer according to one embodiment of the invention is disclosed. A wafer with a silver base 200 is shown. The wafer with a silver base 200 includes a wafer base 202. The wafer base 202 includes a wafer top side 203 and a wafer bottom side 201. In one embodiment, the wafer base 202 is formed from silicon. In one embodiment, the bottom side 105 of the silver base 102 is attached to the wafer top side 203 of the wafer base 202. A wide variety of attachment processes are known to those skilled in the art. In another embodiment, the silver base 200 is deposited on the wafer base 202 through PVD. In this embodiment, the silver that contacts the wafer base 202 is the bottom side 105 and the silver that is exposed to the environment is the top side 107. The protective layer 104 is deposited on the silver base 102 and the wafer 202 through the use of PVD. In one embodiment of the invention, the wafer with a silver base 200 is processed in predetermined patterns for mass production. The predetermined pattern is designed to integrate into a passive or active mirror or electrical circuit. The pattern is changeable and variable as a function of the overall requirements of the production. In another embodiment, the wafer base 202 includes a plurality of layers of semiconductor materials which have been patterned during fabrication of the wafer base 202. In another embodiment, the patterned wafer base 202 may implement one or more electrical components, including but not limited to, a diode, capacitor, transistor, integrated circuitry, and the like. In another embodiment, wafer with a silver mirror 200 is used in the implementation of mirrors, reflectors, light emitting diodes (LEDs), and other applications that require high reflectance.

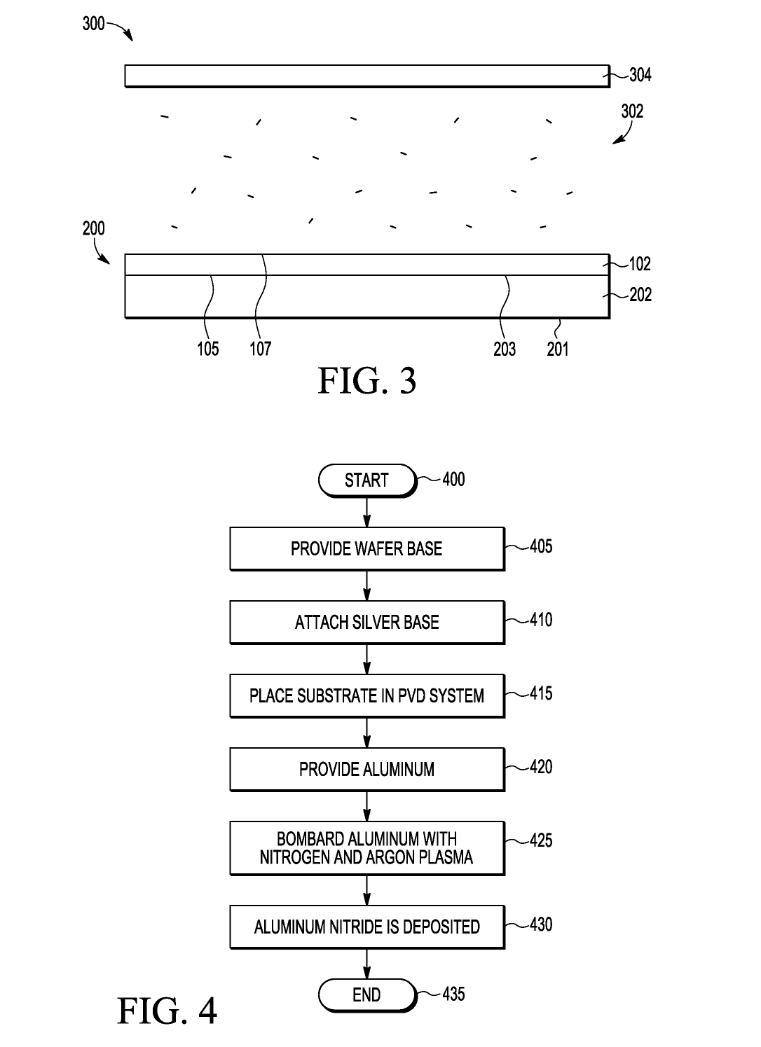

Referring now to FIG. 3, a diagram of a PVD system with a wafer with a silver base according to one embodiment of the invention is disclosed. The PVD system 300 is shown. The wafer with a silver base 200 includes the wafer base 202 and a silver base 102. The wafer with a silver base 200 is the substrate in the PVD process. A metal 304 is provided as the target. In one embodiment, the metal 304 is aluminum. A reactive plasma 302 including nitrogen plasma is used to bombard the aluminum target to nitride the aluminum and deposit the aluminum nitride on the substrate. In another embodiment, the reactive plasma 302 includes nitrogen plasma and argon plasma. The deposited aluminum nitride forms the aluminum nitride protective layer 104. In one embodiment according to the invention, the aluminum nitride protective layer 104 is approximately 200 angstroms thick. An angstrom is a unit of length equal to one hundred-millionth of a centimeter, 10-10 meter. The PVD process provides a uniform protective layer 104 on the silver base 102. The PVD process for aluminum nitride is accomplished in less time than needed to provide an aluminum oxide protective layer. In one embodiment according to the invention, there is approximately a fifty percent (50%) time savings in the aluminum nitride PVD process.

Referring now to FIG. 4, a flow diagram of the deposition of the aluminum nitride layer on the silver base according to one embodiment of the invention is disclosed. The process begins with Start 400. In step 405, a wafer base is provided. A silver base is attached to the wafer base in step 410. A wide variety of attachment processes are known to those skilled in the art. The wafer base with the attached silver base form a substrate. The substrate is placed in the PVD system in step 415. In step 420, aluminum is provided as the metal target in the PVD system. A reactive plasma comprised of nitrogen and argon plasma is used to bombard the aluminum target to nitride the aluminum in step 425. The aluminum nitride is deposited on the substrate in the PVD system in step 430. The aluminum nitride forms the protective layer over the silver base. The process ends in step 435.

Although the invention is described herein with reference to specific embodiments, various modifications and changes can be made without departing from the scope of the invention as set forth in the claims below. Accordingly, the specification and figures are to be regarded in an illustrative rather than a restrictive sense, and all such modifications are intended to be included within the scope of the invention. Any benefits, advantages, or solutions to problems that are described herein with regard to specific embodiments are not intended to be construed as a critical, required, or essential feature or element of any or all the claims.

From time-to-time, the invention is described herein in terms of these example embodiments. Description in terms of these embodiments is provided to allow the various features and embodiments of the invention to be portrayed in the context of an exemplary application. After reading this description, it will become apparent to one of ordinary skill in the art how the invention can be implemented in different and alternative environments. Unless defined otherwise, all technical and scientific terms used herein have the same meaning as is commonly understood by one of ordinary skill in the art to which this invention belongs.

The preceding discussion is presented to enable a person skilled in the art to make and use the invention. The general principles described herein may be applied to embodiments and applications other than those detailed below without departing from the spirit and scope of the invention as defined by the appended claims. The invention is not intended to be limited to the embodiments shown, but is to be accorded the widest scope consistent with the principles and features disclosed herein.

In addition, while a particular feature of the invention may have been disclosed with respect to only one of several embodiments, such feature may be combined with one or more other features of the other embodiments as may be desired. It is therefore, contemplated that the claims will cover any such modifications or embodiments that fall within the true scope of the invention.

The various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the invention. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one”, “one or more” or the like; and adjectives such as “conventional”, “traditional”, “normal”, “standard”, “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the invention may be described or claimed in the singular, the plural is contemplated to be within the scope thereof unless limitation to the singular is explicitly stated.

The presence of broadening words and phrases such as “one or more”, “at least”, “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed across multiple locations.

Unless stated otherwise, terms such as “first” and “second” are used to arbitrarily distinguish between the elements such terms describe. Thus, these terms are not necessarily intended to indicate temporal or other prioritization of such elements.

As used herein, the terms “approximately” and “about” mean within 5 percent, plus or minus, of a given quantity or value. As used herein, the term “nearly” means within 3 percent, plus or minus, of a given quantity or value. As used herein, the terms “substantial” and “substantially” mean sufficient to achieve the stated purpose or value in a practical manner, taking into account any minor imperfections or deviations, if any, that arise from usual and expected process abnormalities that may occur during wafer fabrication, which are not significant for the stated purpose or value.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A semiconductor apparatus, the semiconductor apparatus, comprising:
a wafer base with a top side and a bottom side;
a silver base with a top side and a bottom side, wherein the bottom side of the silver base is attached to the top side of the wafer base and wherein the silver base provides a reflective surface;
an aluminum nitride protective layer attached to the top side of the silver base; wherein the aluminum nitride protective layer shields the silver base from the environment.

2. The semiconductor apparatus of claim 1, wherein the wafer base is formed from silicon.

3. The semiconductor apparatus of claim 1, wherein the wafer base is a patterned wafer base.

4. The semiconductor apparatus of claim 3, wherein the patterned wafer base is a predetermined patterned wafer base.

5. The semiconductor apparatus of claim 1, wherein the aluminum nitride protective layer is attached through physical vapor deposition.

6. The semiconductor apparatus of claim 1, wherein the aluminum nitride protective layer is formed from nitrogen plasma.

7. The semiconductor apparatus of claim 6, wherein the nitrogen plasma is used with argon plasma.

8. The semiconductor apparatus of claim 1, wherein the silver base has a first set of reflective properties.

9. The semiconductor apparatus of claim 8, wherein the first set of reflective properties are unchanged after the attachment of the aluminum nitride protective layer.

10. The semiconductor apparatus of claim 8, wherein the first set of reflective properties are nearly unchanged after the attachment of the aluminum nitride protective layer.

11. The semiconductor apparatus of claim 1 wherein aluminum nitride protective layer is less than 200 angstroms thick.

12. A method for forming a semiconductor apparatus, the method comprising the steps of:
providing a wafer base;
attaching a silver base to the wafer base;
attaching an aluminum nitride protective layer to the silver base.

13. The method of claim 12, wherein the step of attaching the aluminum nitride protective layer to the silver base comprises the deposition of aluminum nitride on to the silver base.

14. The method of claim 13, wherein the step of the deposition of aluminum nitride on to the silver base comprises physical vapor deposition.

15. The method of claim 14, wherein the step of physical vapor deposition comprises bombarding aluminum with nitrogen plasma.

16. The method of claim 15, wherein the step of bombarding aluminum with nitrogen plasma further comprises bombarding aluminum with nitrogen plasma and argon plasma.

17. The method of claim 12, wherein the step of providing a wafer base comprises the step of providing a wafer base formed from silicon.

18. The method of claim 12, wherein the step of providing a wafer base comprises the step of providing a patterned wafer base.

19. The method of claim 18, wherein the step of providing a patterned wafer base comprises the step of providing a predetermined patterned wafer base.

20. The method of claim 12, wherein the step of attaching an aluminum nitride protective layer has no impact to reflective properties of the silver base.
